(19) United States
(12) Patent Application Publication
(10) Pub. No.: US 2006/0046502 A1
(43) Pub. Date: Mar. 2, 2006

(54) Deposition of hard-mask with minimized hillocks and bubbles

(76) Inventors: Minh Van Ngo, Fremont, CA (US); Steven Avanzino, Cupertino, CA (US); Hieu Trung Pham, Milpitas, CA (US); Robert A. Huertas, Hollister, CA (US)

Correspondence Address: LAW OFFICE OF MONICA H CHOI, P O BOX 3424, DUBLIN, OH, 430160204, US

(21) Appl. No.: 10/928,354

(22) Filed: Aug. 27, 2004

(51) Int. Cl. H01L 21/302; H01L 21/31

(52) U.S. Cl. 438/757; 438/791

(57) ABSTRACT

For forming an IC (integrated circuit) structure over a conductive surface, a hard-mask is deposited on the conductive surface with a low temperature in a range of from about 220° Celsius to about 320° Celsius for minimized formation of hillocks. Generally, formation of hillocks and bubbles from deposition of the hard-mask are minimized on the conductive surface. The hard-mask is etched away from the conductive surface, and the IC structure is formed over the conductive surface after the hard-mask is etched away.

### TECHNICAL FIELD

The present invention relates generally to integrated circuit fabrication, and more particularly, to depositing a hard-mask such as a silicon nitride (SiN) hard-mask on a conductive surface such as a copper or copper alloy surface with minimized formation of hillocks and bubbles.

### BACKGROUND OF THE INVENTION

Referring to FIG. 1, a copper or copper alloy structure 102 is formed within a dielectric material 104 disposed over a semiconductor substrate 106. For example, the copper or copper alloy structure 102 may be a damascene interconnect structure. As integrated circuit dimensions are constantly scaled down further, copper with higher electromigration tolerance and lower line resistance is considered a more viable interconnect metal.

Further referring to FIG. 1, a hard-mask 108 is deposited onto an exposed upper surface 110 of the copper or copper alloy structure 102. For example, the hard-mask 108 may be comprised of silicon nitride (SiN). However, in the prior art, bubbles 112 are formed in the hard-mask 108 with corresponding gaps 114 between the hard-mask 108 and the upper surface 110 of the copper or copper alloy structure 102. Alternatively, referring to FIG. 2, hillocks 116 may be formed on the upper surface 110 of the copper or copper alloy structure 102 by the time the SiN hard-mask 108 has been deposited thereon.

Such bubbles 112 and hillocks 116 are detrimental for integrated circuit fabrication. For example, with the bubbles 112 in FIG. 1, an etching solution or other types of reactant may seep into the gaps 114 to degrade the upper surface 110 of the copper or copper alloy structure 102. The poor quality of the upper surface 110 of the copper or copper alloy structure 102 with such degradation from the bubbles 112 or from the hillocks 116 may especially be detrimental when a subsequent IC (integrated circuit) structure is formed thereon.

Thus, a process is desired for minimizing formation of such bubbles 112 and/or hillocks 116 on the surface 110 of the copper or copper alloy structure 102. The present invention herein is described for an example embodiment of the copper or copper alloy structure 102. However, the present invention may also be applied for minimizing such bubbles 112 and hillocks 116 for other types of interconnect structures comprised of materials aside from the example of copper or copper alloy.

### SUMMARY OF THE INVENTION

Accordingly, a general aspect of the present invention includes a method of fabricating an IC (integrated circuit) structure over a conductive surface, with minimized formation of bubbles and hillocks thereon from deposition of a hard-mask.

In one embodiment of the present invention, for forming an IC (integrated circuit) structure over a conductive surface, a hard-mask is deposited on the conductive surface with a low temperature in a range of from about 220° Celsius to about 320° Celsius for minimized formation of hillocks on the conductive surface. The hard-mask is etched away from the conductive surface, and the IC structure is formed over the conductive surface after the hard-mask is etched away.

In an example embodiment, the conductive surface is a copper or copper alloy surface, and the hard-mask is a silicon nitride (SiN) hard-mask. In that case, the SiN hard-mask is deposited in an ULDR (ultra low deposition rate) PECVD (plasma enhanced chemical vapor deposition) process such that the SiN hard-mask has a thickness in a range of from about 80 Å to about 120 Å.

In another embodiment, dual RF (radio frequency) powers are applied including HF (high frequency) power applied on a plasma electrode and LF (low frequency) power applied on a heater block during deposition of the SiN hard-mask that is compressive.

Bubble formation is minimized in the SiN hard-mask by pre-treating the copper or copper alloy surface with hydrogen-based plasma. In one example embodiment, the pre-treatment of the copper or copper alloy surface is performed for a short time period in a range of from about 2 seconds to about 5 seconds.

In another embodiment, a temperature soak is performed at a temperature in a range of from about 220° Celsius to about 320° Celsius, before the step of depositing the SiN hard-mask. In an example embodiment, the temperature soak is performed for a short time period in a range of from about 2 seconds to about 5 seconds.

In yet another example embodiment, the IC structure is comprised of polymer layers formed from the copper or copper alloy surface to form a polymer memory cell in a BEOL (back end of line) process. Alternatively, the IC structure is a diffusion barrier structure such as a tantalum cap formed over the copper or copper alloy surface.

In this manner, the present invention minimizes formation of SiN bubbles and copper hillocks from deposition of the SiN hard-mask on the copper or copper alloy surface. With such minimized defects on the copper or copper alloy surface, performance of the IC structure formed over the copper or copper alloy surface is enhanced.

These and other features and advantages of the present invention will be better understood by considering the following detailed description of the invention which is presented with the attached drawings.

### BRIEF DESCRIPTION OF THE DRAWINGS

FIG. 1 shows deposition of a silicon nitride (SiN) hard-mask on a copper or copper alloy surface with disadvantageous formation of bubbles, according to the prior art;

FIG. 2 shows deposition of the silicon nitride (SiN) hard-mask with disadvantageous formation of hillocks on the copper or copper alloy surface, according to the prior art;

FIG. 3 shows a block diagram of components of a PECVD (plasma enhanced chemical vapor deposition) system used for deposition of a hard-mask on the copper or copper alloy surface with minimized formation of hillocks and bubbles, according to an embodiment of the present invention;

FIG. 4 shows a flow-chart of steps for forming an IC structure on the copper or copper alloy surface after etching away the hard-mask deposited with the PECVD system of FIG. 3, according to an embodiment of the present invention; and

FIGS. 5-10 show cross-sectional views for forming an IC structure on the copper or copper alloy surface after etching away the hard-mask deposited with the PECVD system of FIG. 3, according to an embodiment of the present invention.

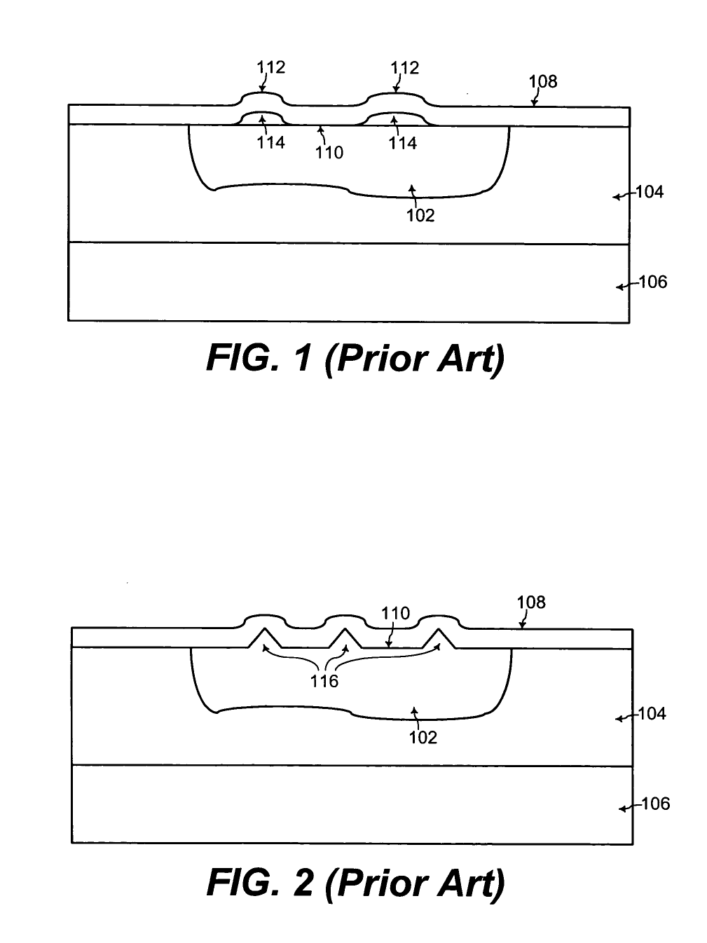

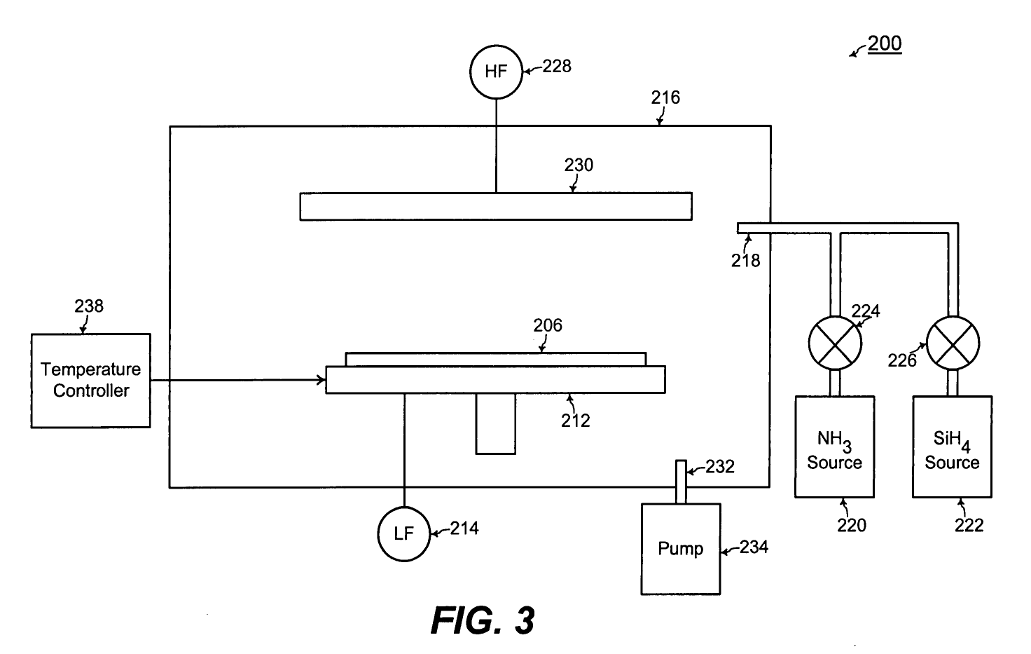

The figures referred to herein are drawn for clarity of illustration and are not necessarily drawn to scale. Elements having the same reference number in FIGS. 1, 2, 3, 4, 5, 6, 7, 8, 9, and 10 refer to elements having similar structure and function.

### DETAILED DESCRIPTION

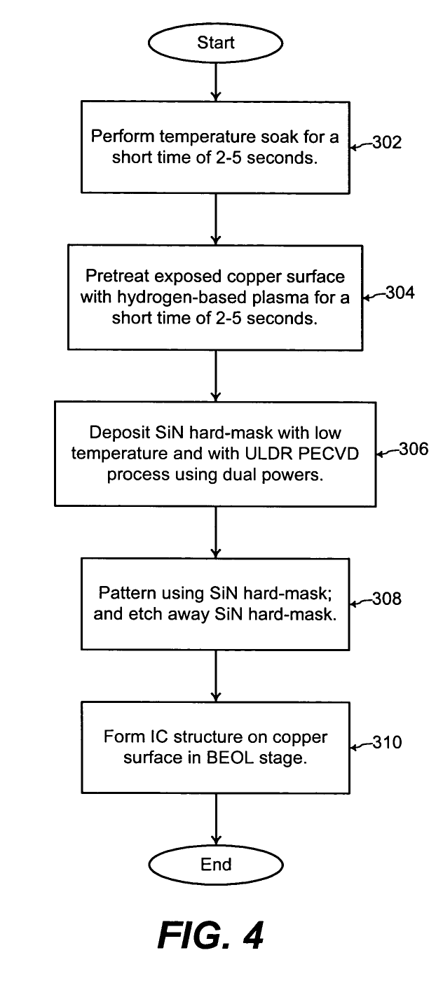

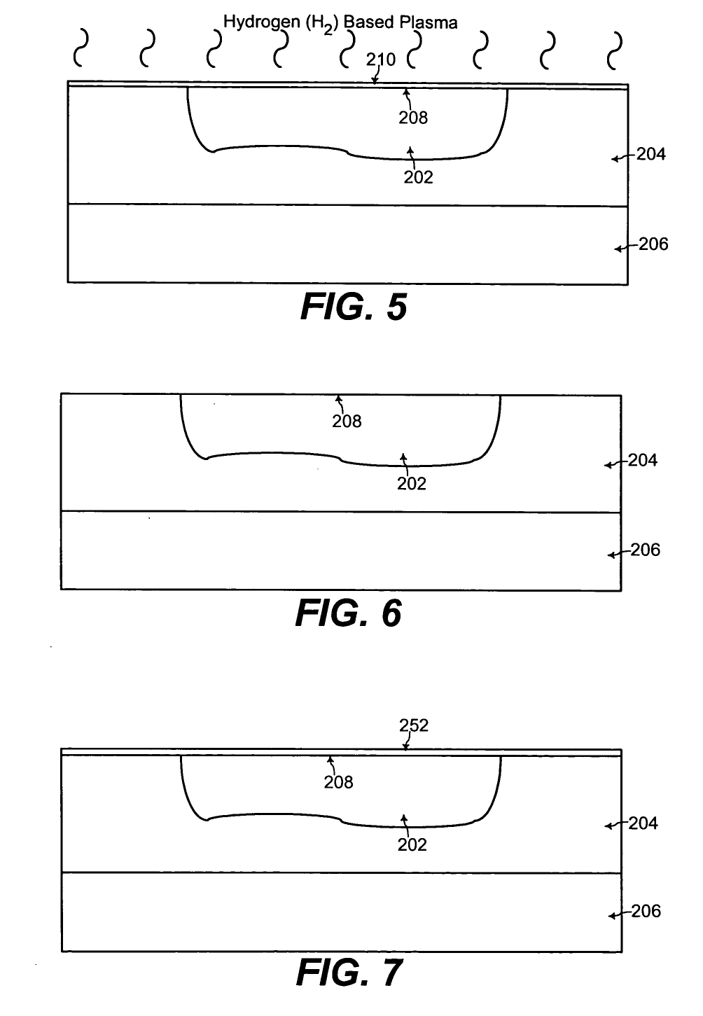

FIG. 3 illustrates a PECVD (plasma enhanced chemical vapor deposition) system 200 for depositing a silicon nitride (SiN) hard-mask on a copper or copper alloy surface. FIG. 4 shows a flow-chart of steps for forming an IC structure on the copper or copper alloy surface after etching away the hard-mask deposited with the PECVD system of FIG. 3.

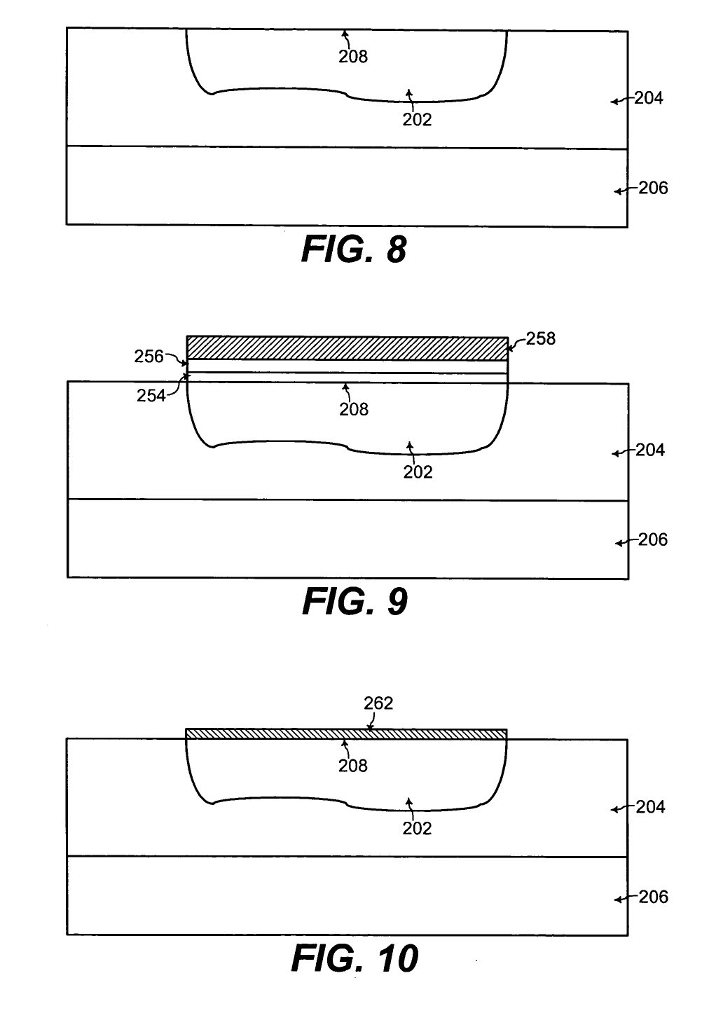

FIG. 5 shows a cross-sectional view of a copper or copper alloy structure 202 formed within a dielectric 204 deposited over a semiconductor substrate 206. For example, the copper or copper alloy structure 202 may be part of an interconnect structure formed in a single or dual damascene process. Alternatively, the copper or copper alloy structure 202 may be a plug formed as an electrode for a polymer memory cell in a BEOL (back end of line) process.

In addition, the semiconductor substrate 206 is comprised of a silicon wafer according to one embodiment of the present invention. When the dielectric 204 is comprised of silicon dioxide (SiO₂), the copper or copper alloy structure 202 is surrounded by a diffusion barrier layer (not shown in FIGS. 5-10) at the interface between the copper or copper alloy structure 202 and the dielectric 204.

Referring to FIG. 3, the PECVD system 200 includes a wafer chuck 212 having the semiconductor substrate 206 placed thereon. The wafer chuck 212 also acts as a heater block for heating the semiconductor substrate 206 placed thereon. A LF (low frequency) power source 214 is coupled to the heater block 212. The PECVD system 200 also includes a deposition chamber 216 with reactants flowing therein via an inlet 218. For example, the reactants include a NH₃ source 220 and a SiH₄ source 222. A first valve 224 is adjusted for controlling the flow rate of NH₃ into the deposition chamber 216, and a second valve 226 is adjusted for controlling the flow rate of SiH₄ into the deposition chamber 216.

A HF (high frequency) power source 228 is coupled to a plasma electrode 230 that energizes the NH₃ and/or SiH₄ reactants to form plasma. In addition, an outlet 232 and a pump 234 take away by-products produced from deposition of the hard-mask out of the deposition chamber 216. Furthermore, a temperature controller 238 is coupled to the heater block 212 for determining the temperature of the heater block 212.

Referring to FIG. 5, typically a CMP process (chemical mechanical polishing) process is performed such that the copper or copper alloy structure 202 is contained within the dielectric 204 and such that an upper surface 208 of the copper or copper alloy structure 202 is exposed. Typically, a very thin layer of copper oxide 210 forms on the upper surface 208 of the copper or copper alloy structure 202 after the CMP process.

Referring to FIGS. 3, 4, and 5, the semiconductor substrate 206 having such a copper or copper alloy structure 202 is placed on the heater block 212 within the deposition chamber 216. Thereafter, a temperature soak is performed (step 302 of FIG. 3). A temperature soak refers to the step of heating the semiconductor substrate 206 with any IC structures formed thereon to a predetermined temperature for a predetermined time period within the deposition chamber 216 before subsequent processing steps. In one embodiment of the present invention, the temperature soak is performed with the temperature of the heater block 212 set in a range of from about 220° Celsius to about 320° Celsius. In addition, such a temperature soak is performed for a relatively short time period in a range of 2 seconds to 5 seconds, in an embodiment of the present invention.

After the temperature soak, to remove the thin layer of copper oxide 210, the copper or copper alloy surface 208 is pre-treated with a hydrogen (H₂) based plasma (step 304 of FIG. 4). For such pre-treatment:
the first valve 224 is used to flow NH₃ into the deposition chamber 216 at a flow rate in a range of from about 600 sccm to about 1,000 sccm;
the pressure within the deposition chamber 216 is set to be in a range of from about 1 Torr to about 2 Torr;
a temperature within the deposition chamber 216 is set to be in a range of from about 220° Celsius to about 320° Celsius; and
HF (high frequency) power from the HF source 214 in a range of from about 300 watts to about 400 watts is applied on the plasma electrode 230.

During this pre-treatment, the second valve 226 is closed such that SiH₄ does not flow into the deposition chamber 216, and the LF (low frequency) power source 214 is turned off to not apply LF power on the heater block 212. Furthermore, this pre-treatment is performed for a relatively short time period in a range of 2 seconds to 5 seconds, in an embodiment of the present invention. Referring to FIGS. 5 and 6, after such a pre-treatment process, the thin layer of copper oxide 210 is substantially removed from the exposed surface 208 of the copper or copper alloy structure 202.

Referring to FIGS. 6 and 7, after the pre-treatment, a silicon nitride (SiN) hard-mask 252 is deposited onto the copper or copper alloy surface 208 within the deposition chamber 216 (step 306 of FIG. 4). In an important aspect of the present invention, the SiN hard-mask 252 is deposited using a relatively low temperature in a range of from about 220° Celsius to about 320° Celsius to minimize formation of hillocks on the surface 208 of the copper or copper alloy structure 202. In the prior art, a temperature near about 400° Celsius is typically used for deposition of a SiN hard-mask.

In an embodiment of the present invention, an ULDR (ultra low deposition rate) PECVD process is used for deposition of the SiN hard-mask 252. For such an ULDR PECVD process:
the first valve 224 is used for flowing NH₃ at a flow rate in a range of from about 600 sccm to about 1,000 sccm into the deposition chamber 216;
the second valve 226 is used for flowing SiH₄ at a flow rate in a range of from about 65 sccm to about 135 sccm into the deposition chamber 216;
a pressure within the deposition chamber 216 is set to be in a range of from about 1 Torr to about 2 Torr;
a temperature within the deposition chamber is set to be relatively low in a range of from about 220° Celsius to about 320° Celsius;
HF (high frequency) power from the HF source 228 in a range of from about 300 watts to about 400 watts is applied on the plasma electrode 230; and
LF (high frequency) power from the LF source 214 in a range of from about 100 watts to about 200 watts is applied on the wafer chuck 212.

Generally, for such an ULDR PECVD process, relatively low flow rates of the reactants NH₃ and SiH₄, a low pressure, and a low temperature within the deposition chamber 216 are used for a low deposition rate of 400 Å-600 Å/minute for the SiN hard-mask 252. In one embodiment of the present invention, the SiN hard-mask 252 is deposited to have a thickness in a range of from about from about 80 Å to about 120 Å. Furthermore, dual powers of the HF power applied on the plasma electrode 230 and the LF power applied on the heater block 212 are used to form the SiN hard-mask 252 that is compressive rather than tensile.

According to an aspect of the present invention, use of the relatively low temperature in a range of from about 220° Celsius to about 320° Celsius results in minimized formation of hillocks on the surface 208 of the copper or copper alloy structure 202 from deposition of the SiN hard-mask 252. In the prior art, a higher temperature of near 400° Celsius is used to deposit a SiN hard-mask because qualities of the SiN hard-mask deposited at such a higher temperature are desired when the SiN hard-mask is deposited before the BEOL (back end of line) process. BEOL refers to fabrication steps performed for forming interconnect structures such as contacts after fabrication of integrated circuit structures into the semiconductor substrate 206 in the FEOL (front end of line) process.

The SiN hard-mask 252 of the embodiment of the present invention is contemplated for being used in the BEOL process with the SiN hard-mask eventually being substantially etched away. Thus, the qualities of the SiN hard-mask achievable with the higher deposition temperature of near 400° Celsius of the prior art is traded off for minimizing formation of the hillocks by using the lower deposition temperature of from about 220° Celsius to about 320° Celsius, according to an aspect of the present invention.

Furthermore, the pre-treatment (step 304 of FIG. 4) for removal of the thin layer of copper oxide 210 minimizes formation of bubbles for the SiN hard-mask 252. Performing the temperature soak (step 302 of FIG. 4) and the pre-treatment (step 304 of FIG. 4) for the relatively short time period of 2-5 seconds further minimizes formation of bubbles and hillocks at the surface 208 of the copper or copper alloy structure 202. Applicants have verified such minimized formation of bubbles and hillocks with SEM (scanning electron microscopy) images.

Referring to FIGS. 7 and 8, the SiN hard-mask 252 is used for integrated circuit fabrication such as for patterning other IC (integrated circuit) material on the semiconductor substrate 206 for example (step 308 of FIG. 4). After the SiN hard-mask 252 is used, the SiN hard-mask 252 is etched away (step 308 of FIG. 4). Processes for etching away the SiN hard-mask 252 are individually known to one of ordinary skill in the art of integrated circuit fabrication.

Referring to FIGS. 8 and 9, after the SiN hard-mask 252 is etched away from the surface 208 of the copper or copper alloy structure 202, an IC structure is formed on the conductive surface 208 of the copper or copper alloy structure 202 (step 310 of FIG. 4). For example, referring to FIG. 9, the IC structure includes a passive polymer layer 254, an active polymer layer 256, and an upper conductive layer 258 stacked onto the copper or copper alloy surface 208 to form a polymer memory cell in a BEOL (back end of line) process. Polymer memory cells individually by themselves are known to one of ordinary skill in the art.

Alternatively, referring to FIGS. 8 and 10, the IC structure formed on the copper or copper alloy surface 208 is a diffusion barrier structure such as a tantalum cap 262. The tantalum cap 262 is formed on the upper surface 208 of the copper or copper alloy structure 202 to prevent diffusion and migration of copper from the copper or copper alloy structure 202.

In any case, with minimized formation of bubbles and/or hillocks on the surface 208 of the copper or copper alloy structure 202 after formation of the SiN hard-mask 252 in FIG. 7, the integrity of such a high quality surface 208 is enhanced. Thus, performance of the IC structure formed onto such a surface 208 in FIGS. 9 and 10 is in turn enhanced. For example, with a smooth well-preserved copper or copper alloy surface 208, the performance of the polymer memory cell in FIG. 9 is enhanced for charge storage control within the polymer layers 254 and 256.

Furthermore, with minimized formation of hillocks on the copper or copper alloy surface 208, the tantalum cap 262 is formed with minimized discontinuity and peeling. Additionally, use of dual powers of the HF power applied on the plasma electrode 230 and the LF power applied on the heater block 212 results in the SiN hard-mask 252 that is more compressive (i.e., of higher density) rather than tensile. Because tantalum is tensile, deposition of the SiN hard-mask 252 that is compressive (in step 306 of FIG. 4) results in less peeling of the tantalum cap 262 in FIG. 10.

The foregoing is by way of example only and is not intended to be limiting. For example, the present invention herein is described for an example embodiment of the copper or copper alloy structure 202. However, the present invention may also be applied for minimizing bubbles and hillocks for other types of interconnect structures comprised of materials aside from the example of copper or copper alloy.

Additionally, the present invention is described in reference to example layers deposited directly on top of each-other. However, the present invention may be practiced with other intervening layers of material. Thus, when a first layer is described as being deposited on a second layer, an intervening layer may also be formed between the first and second layers. In addition, the materials described herein are by way of example only. Furthermore, any dimensions or parameters specified herein are by way of example only. The present invention is limited only as defined in the following claims and equivalents thereof.

We claim:

1. A method for forming an IC (integrated circuit) structure, comprising:
A. depositing a hard-mask on a conductive surface with a low temperature in a range of from about 220° Celsius to about 320° Celsius for minimized formation of hillocks;
B. etching away the hard-mask from the conductive surface; and
C. forming the IC structure over the conductive surface after step B.

2. The method of claim 1, wherein the conductive surface is a copper or copper alloy surface, and wherein the hard-mask is a silicon nitride (SiN) hard-mask.

3. The method of claim 2, wherein the SiN hard-mask is deposited in an ULDR (ultra low deposition rate) PECVD (plasma enhanced chemical vapor deposition) process.

4. The method of claim 3, wherein the SiN hard-mask has a thickness in a range of from about 80 Å to about 120 Å.

5. The method of claim 3, wherein the ULDR PECVD process includes the steps of:
flowing NH₃ at a flow rate in a range of from about 600 sccm to about 1,000 sccm;
flowing SiH₄ at a flow rate in a range of from about 65 sccm to about 135 sccm;
setting a pressure to be in a range of from about 1 Torr to about 2 Torr;
setting a temperature to be in a range of from about 220° Celsius to about 320° Celsius;
applying HF (high frequency) power in a range of from about 300 watts to about 400 watts on a plasma electrode; and
applying LF (high frequency) power in a range of from about 100 watts to about 200 watts on a wafer chuck.

6. The method of claim 2, further including the step of:
applying dual powers including HF (high frequency) power applied on a plasma electrode and LF (low frequency) power applied on a heater block during deposition of the SiN hard-mask that is compressive.

7. The method of claim 2, further comprising:
performing a temperature soak at a temperature in a range of from about 220° Celsius to about 320° Celsius, before step A.

8. The method of claim 7, wherein the temperature soak is performed for a short time period in a range of from about 2 seconds to about 5 seconds.

9. The method of claim 7, further comprising:
minimizing bubble formation in the SiN hard-mask by pre-treating the copper or copper alloy surface with hydrogen based plasma, after the temperature soak.

10. The method of claim 9, wherein the pre-treatment of the copper or copper alloy surface is performed for a short time period in a range of from about 2 seconds to about 5 seconds.

11. The method of claim 10, wherein the pre-treatment of the copper or copper alloy surface includes the steps of:
flowing NH₃ at a flow rate in a range of from about 600 sccm to about 1,000 sccm;
setting a pressure to be in a range of from about 1 Torr to about 2 Torr;
setting a temperature to be in a range of from about 220° Celsius to about 320° Celsius; and
applying HF (high frequency) power in a range of from about 300 watts to about 400 watts on a plasma electrode.

12. The method of claim 2, wherein the IC structure is comprised of polymer layers formed from the copper or copper alloy surface to form a polymer memory cell in a BEOL (back end of line) process.

13. The method of claim 2, wherein the IC structure is a diffusion barrier structure formed over the copper or copper alloy surface.

14. The method of claim 13, wherein the diffusion barrier structure is a tantalum cap.

15. The method of claim 1, wherein the IC structure is comprised of polymer layers formed from the conductive surface to form a polymer memory cell in a BEOL (back end of line) process.

16. The method of claim 1, wherein the IC structure is a diffusion barrier structure formed over the conductive surface.

17. The method of claim 16, wherein the diffusion barrier structure is a tantalum cap.

18. The method of claim 1, further comprising:
performing a temperature soak at a temperature in a range of from about 220° Celsius to about 320° Celsius, before step A.

19. The method of claim 18, wherein the temperature soak is performed for a short time period in a range of from about 2 seconds to about 5 seconds.

20. The method of claim 18, further comprising:
minimizing bubble formation in the hard-mask by pre-treating the conductive surface with hydrogen based plasma, after the temperature soak.

21. The method of claim 20, wherein the pre-treatment of the conductive surface is performed for a short time period in a range of from about 2 seconds to about 5 seconds.

22. A method for forming an IC (integrated circuit) structure over a conductive surface, comprising:
A. performing a temperature soak at a temperature in a range of from about 220° Celsius to about 320° Celsius for a short time period in a range of from about 2 seconds to about 5 seconds;
B. pre-treating the conductive surface with a hydrogen based plasma for a short time period in a range of from about 2 seconds to about 5 seconds;
C. depositing a silicon nitride (SiN) hard-mask on the conductive surface with a low temperature in a range of from about 220° Celsius to about 320° Celsius for minimized formation of hillocks during an ULDR (ultra low deposition rate) PECVD (plasma enhanced chemical vapor deposition) process;
D. applying dual powers including HF (high frequency) power applied on the plasma electrode and LF (low frequency) power applied on a heater block for deposition of the SiN hard-mask that is compressive;
E. etching away the SiN hard-mask from the conductive surface; and
F. forming the IC structure over the conductive surface.

23. A method for forming an IC (integrated circuit) structure over a copper or copper alloy surface, comprising:
A. performing a temperature soak at a temperature in a range of from about 220° Celsius to about 320° Celsius for a short time period in a range of from about 2 seconds to about 5 seconds;
B. pre-treating the copper or copper alloy surface with a hydrogen based plasma for a short time period in a range of from about 2 seconds to about 5 seconds, including the steps of:
flowing NH₃ at a flow rate in a range of from about 600 sccm to about 1,000 sccm;
setting a pressure to be in a range of from about 1 Torr to about 2 Torr;
setting a temperature to be in a range of from about 220° Celsius to about 320° Celsius; and
applying HF (high frequency) power in a range of from about 300 watts to about 400 watts on a plasma node;
C. depositing a silicon nitride (SiN) hard-mask on the copper or copper alloy surface with a low temperature in a range of from about 220° Celsius to about 320° Celsius for minimized formation of hillocks on the copper or copper alloy surface during an ULDR (ultra low deposition rate) PECVD (plasma enhanced chemical vapor deposition) process that includes the steps of:
flowing NH₃ at a flow rate in a range of from about 600 sccm to about 1,000 sccm;
flowing SiH₄ at a flow rate in a range of from about 65 sccm to about 135 sccm;
setting a pressure to be in a range of from about 1 Torr to about 2 Torr;
setting a temperature to be in a range of from about 220° Celsius to about 320° Celsius;
applying a HF (high frequency) power in a range of from about 300 watts to about 400 watts on a plasma electrode; and
applying a LF (low frequency) power in a range of from about 100 watts to about 200 watts on a wafer chuck;
wherein the SiN hard-mask that is compressive is deposited to a thickness in a range of from about 80 Å to about 120 Å;
D. etching away the SiN hard-mask from the copper or copper alloy surface; and
E. forming the IC structure over the copper or copper alloy surface, wherein the IC structure is one of a tantalum cap or polymer layers of a polymer memory cell in a BEOL (back end of line) process.
